(19) United States
(12) Patent Application Publication
(10) Pub. No.: US 2014/0230885 A1
(43) Pub. Date: Aug. 21, 2014

(54) PHOTOVOLTAIC DEVICES

(71) Applicant: EIGHT19 LIMITED, Cambridge, Cabrimdgeshire (GB)

(72) Inventors: John Richard Fyson, London (GB); Jurjen Frederick Winkel, Ely Cambridgeshire (GB); MIchael Niggermann, Cambridge Cambridgeshire (GB); Simon Barns-Field-Garth, Ickleton Cambridgeshire (GB)

(21) Appl. No.: 14/346,037

(22) PCT Filed: Sep. 20, 2012
(86) PCT No.: PCT/GB2012/052330

§ 371 Date: Mar. 20, 2014

(30) Foreign Application Priority Data
Sep. 20, 2011 (GB) 1116253.4

(51) Int. Cl. H01L 27/142; H01L 27/30

(52) U.S. Cl. CPC H01L 27/142; H01L 27/301
USPC 136/251

(57) ABSTRACT

In order to mitigate tampering with a solar cell, the present invention provides a photovoltaic device comprising at least one photovoltaic cell housed within an encapsulant forming a protective barrier for the at least one photovoltaic cell; a switch operable to allow delivery of electricity from the device; and means, also housed within the encapsulant, to render the device inoperable, preferably permanently inoperable, upon tampering with the device.

The present invention relates to photovoltaic devices for converting solar energy into electrical energy.

Solar power has enabled significant progress in the provision of electricity for remote areas or communities not served by a national grid system. Energy poverty is a major concern for a number of third world countries and has led, for example, to the development of solar lanterns as replacements for kerosene lanterns. Such improvements bring enormous health benefits as well as the environmental advantage of reducing carbon emissions. However, the availability of solar power is hampered by the large cost barrier associated with the purchase and management of a solar energy supply and even solar lanterns are not affordable to many households in for example large parts of Africa and Asia. For this reason, various schemes have been proposed based on a micro-finance or micro-consignment business model in which the consumer only pays for the electricity generated and not for the device. One such example is described in US2010/174642 in which a payment provides a key which can be used to enable the one or more charge and discharge cycles of a solar powered charger.

A first aspect of the present invention provides a photovoltaic device comprising: at least one photovoltaic cell housed within an encapsulant forming a protective barrier for the at least one photovoltaic cell; a switch operable to allow delivery of electricity from the device; and means, also housed within the encapsulant, to render the device inoperable, preferably permanently inoperable, upon tampering with the device.

Preferably, the encapsulant comprises a barrier layer over front and back sides of the device or the means to render the device inoperable are located adjacent an electrode, either an anode or cathode electrode. More preferably, the means to render the device inoperable are located between a substrate supporting an electrode and the encapsulant.

An adhesive may be used to join a barrier layer over front and back sides of the device. A thermal melt adhesive may be used as well as other adhesive/laminating additive or a viscous grease.

In a preferred embodiment, the switch is also housed within the encapsulant.

Optionally, the switch may be controlled by an integrated circuit.

The integrated circuit and/or switch may be an integral component of the PV device.

The means to render the device inoperable may render the device permanently or reversibly inoperable.

The photovoltaic cell may be an organic photovoltaic cell.

The device may have a terminal for connection to a load.

The means may be upstream or downstream of the terminal.

The device may comprise a plurality, i.e. two, three or more, photovoltaic cells. The means to render the device inoperable may be located between individual cells and/or between the first and/or last cell and a respective terminal.

The means to render the device inoperable may comprise means to short circuit the at least one cell.

The means to render the device inoperable may comprise means to short circuit every cell.

If present, multiple cells may be short circuited and/or the whole device may be short circuited.

The means to render the device inoperable may comprise means to at least partially inhibit, e.g. to interrupt, the current flow of interconnected cells.

If present, the means to short circuit the at least one cell may be connected in parallel to a bypass diode.

The means to render the device inoperable may comprise means to partially or completely interfere with collection of solar energy (e.g. to shade) the at least one cell.

If present, multiple cells may have their solar collection interfered with (e.g. shaded) by the means to render the device inoperable.

The means to render the device inoperable may comprise channels which are revealed upon tampering with the switch and/or, if present, the integrated circuit. The channels may be formed within the encapsulant at a side facing the at least one photovoltaic cell or formed within a substrate supporting an electrode upon which at least one layer of the at least one photovoltaic cell is mounted.

The channels may be air pockets or filled with materials which react with components in the air, e.g. oxygen and/or moisture.

A getter material may be included in the device, e.g. evaporated (flashed getters), barium, aluminium, magnesium, calcium, sodium, strontium, caesium, phosphorous, humidity getters such as Dynic HG sheet, Sud-Chemie Desi Paste, Zeolites or Zeolitic clays.

The means to render the device inoperable may comprise a chemical switch. The chemical switch may remove or degrade the electrical interface between a stripe electrode and a busbar.

The chemical switch may be instigated as a result of oxidation or water (vapour) ingress after puncture of a barrier.

The chemical switch may comprise a material which reacts with oxygen or moisture to generate an aggressive chemical which attacks a component of the device e.g. an electrode material, e.g. the material may comprise white phosphorous.

The means to render the device inoperable may comprise a material which swells in the presence of moisture, e.g. a dry starch, gel, swellable polymer, a mineral clay, or a combination thereof, to electrically separate the electrode and busbar by swell induced physical separation.

The means to render the device inoperable may comprise a conductive liquid which makes a vital connection which leaks away upon tampering with the switch.

The means to render the device inoperable may comprise a conductive liquid which short circuits the at least one cell on tampering with the switch.

The conductive liquid may comprise an ionic liquid e.g. 1-ethyl-3-methylimidazlium dicyanamide, (C₂H₅)(CH₃)C₃H₃N⁺₂.N(CN)⁻₂ or 1-butyl-3,5-dimethylpyridinium bromide; a solution of electrolyte e.g an inorganic liquid/solvent, for example the solvent may comprise a nitrile such as acetonitrile, acrylonitrile or propionitrile, a sulfoxide such as dimethyl, diethyl, ethyl methyl and benzylmethyl sulfoxide, an amide such as dimethyl formamide and pyrrolidones such as N-methylpyrrolidone or a carbonate such as propylene carbonate and the electrolyte salt may comprise quaternary ammonium salts such as tetraethylammonium tetrafluoroborate ((Et)₄ NBF₄) hexasubstituted guanidinium salts; or a liquid metal or alloy such as mercury, gallium, sodium-potassium or galinstan.

Preferably, capillary force is used to induce liquid flow upon tampering.

Alternatively, the means to render the device inoperable may comprise a corrosive or aggressive liquid chemical, chemicals or etchants delivered to key interfaces, e.g. by capillary force.

Preferably, the liquid is stored in a reservoir and is released upon tampering.

Preferably, the liquid is stored under encapsulation.

The means to render the device inoperable may comprise light activated short circuiting.

The means to render the device inoperable may further comprise light guiding features.

If present, multiple cells may be short circuited or the whole device may be short circuited.

The means to render the cell inoperable may comprise a ZnO photosensitive diode switch.

The means to render the device inoperable may comprise at least one field effect transistor.

The means to render the device inoperable may comprise a substantially transparent layer of material which turns opaque upon tampering with the switch.

The layer may comprise a dye, such as a Leuco dyes, e.g. crystal violet lactone, phenolphthalein, or thymolphthalein.

The layer may comprise an electrochromic dye or dyes or a bistable liquid crystal.

The means to render the device inoperable may comprise a liquid dye.

Preferably, the liquid is stored in a reservoir and is released upon tampering.

Preferably, the liquid is stored under encapsulation.

Embedded integrated Circuits (ICs) for solar cells are an extension of a standard requirement for most solar module installations where ensuring the solar module is operating at its optimum level for a given set of environmental conditions is typically managed by a Maximum Peak Power Tracking (MPPT) unit, which use standard algorithms to apply a variable load on the cells to set the inverter to draw a current from the device to generate the maximum power obtainable.

With some modification, where the IC has enhanced information processing capability, it is known that the IC involved can also be advantageously used to fulfill other useful functions such as routine monitoring the cell performance statistically and communicating the results to a central monitoring facility. This solar module monitoring information is of use in terms of for instance early failure detection, producing maps of insolation if positioning data were available from e.g. cellular triangulation or GPS transceiver and can enable sophisticated inline or pre-release testing during manufacturing and potentially even dynamic self-repair either pre factory release or during day to day operations.

More advanced functionality can also be added, such as the security components required to enable a micropayment or micro-consignment scheme. For these schemes the requirements are that there is a secure authentication process and this can be achieved by adding an embedded security module to provide trusted hardware or suitably encrypted communications which could in principle be used for secure payments to be made. The device may for instance be able to generate its own secure key from some of its operational records.

Further use can be made of the operation data collected such as Carbon Credit accounting and to obtain carbon credits where the IC has suitable associated trusted hardware. Other benefits include the ability to apply subsidy, warrantee or credit; to make counterfeiting detectable and more challenging; provide serial or tracking IDs, time and date stamps, certification, service & guarantee schemes, as well as ensuring adherence to accepted standards (e.g. communication).

Whilst all of the additional functionality can be provided by an IC remote from the solar cell there are significant benefits to embedding the at least one secure component of the electronic control system within the framework of the solar cell. Here embedded means part of the same assembly or mechanical unit, e.g. sealed within the same weather-proof encapsulation or mounted directly onto the solar module. The electronics interpretation of embedded, where there are direct electrical connections between the solar cell and the embedded components, is also applicable.

Aside from the potential material usage benefits of embedding the electronics within the solar module, there is also an added benefit that the system becomes intrinsically more secure, in that it is much harder to separate the IC from the solar module, thus making it less desirable to steal the device, especially where the device requires secure authentication to function properly. A further benefit is to have the IC act in a way so that tampering with the solar module results in a temporary or even permanent change in behaviour of the IC in terms of the information transmitted via the IC and potentially also the ability of the device to produce power electronically.

An embedded IC can be extremely simple and for instance be used exclusively for signal authentication and power switching. This can be usefully employed for micropayments applications where there is a requirement to have an electronic switch to the device busbar as a security feature to ensure that the solar module does not function upon removal of the, in this instance separate, micropayment control unit connected via a physical cable.

Moreover, by definition an IC will generally be a relatively small component on a comparatively large solar cell. What this means is that a user may be able to physically remove the IC from the weather proof encapsulation, or potentially isolate or circumvent the key contact points of the IC, rendering the IC inoperable. Without the IC electrically connected, any inbuilt electronic means of disabling the cell will not work. If said skilled person were then to electrically connect the solar module to a separate MPPT unit, the authentication and security features would have been circumvented and the solar cell would be effectively operable. The present invention overcomes this disadvantage by rendering the device inoperable, preferably permanently, upon tampering.

This circumvention of the IC is a particular issue when micropayment methods are employed. Whereas for non-micropayment solutions the threat to the solar module is largely from theft of the unit, micropayment schemes subsidise the original purchase price of solar modules by the revenue stream from repeated and/or continued use of the device. There may thus be temptation for the owners of such devices to try to evade the payment mechanism.

Photovoltaic modules are typically covered with a transparent protective material which has the advantage of making the devices more robust to physical damage, as well as protecting them from the elements. For Si based devices this layer can be a coated or cast layer or an applied barrier material, such as a plastic substrate or a sheet of glass. These plastic substrates are typically applied with an adhesive made of EVA (ethylene-vinyl acetate), although many other materials have been developed over the years as adhesive layer with enhanced light and thermal stability, weather-proofing capability, etc.

For thin film solar cells and modules protective barriers with improved moisture and oxygen transmission characteristics have been developed, as many of the materials that are used to produce the solar devices are susceptible to degradation in the presence of moisture and oxygen. Correspondingly it is typically a requirement to fully encapsulate these devices in such a way as to ensure that no oxygen or moisture ingress occurs, or at the very least occurs at a very significantly reduced rate, through the front, the back or the edges of the PV module. Barrier requirements vary depending on the material sets employed, but as an example for Organic Photovoltaic devices, barrier film properties in the order of 10-4 g/m2/day MVTR (moisture vapour transmission rate), as for instance measured using a MOCON test (typically carried out at near 100% humidity at elevated temperatures), are currently required to provide commercially relevant device lifetimes.

One option for oxygen or moisture sensitive devices is to encapsulate devices with glass on the front side as this has extremely good barrier properties, although drawbacks are the inherent mass and/or fragility of cost effective glass materials, especially where it is employed in larger modules.

An alternative option for the transparent side is to use a polymeric film with an integrated barrier. High barrier films are typically produced using successive inorganic/organic stacks, with the number of dyads determining the final barrier properties. Additionally it is an option to include oxygen or moisture absorbing/scrubbing materials in these layers to further improve permeation rates. Examples of these high barrier materials include Barix multilayers and film materials produced by Alcan and 3M amongst others.

Similar materials can be used for the back side encapsulation, although as it is not a requirement for the back side encapsulation to be transparent in many instances. A more typical configuration is to make use of an opaque barrier as these can be manufactured at significantly lower cost for instance by thermal evaporation of a layer of suitably high barrier metal or even use of thin metal sheets with a suitable dielectric adhesive layer.

Oxygen and moisture ingress from the edges can be minimised by use of high barrier adhesives (low WVTR) to attach the two barriers to the PV module. The adhesives could in principle be of any type, but it is important that the correct chemical and mechanical synergies are achieved. The adhesive can be coated, or can be a pressure sensitive adhesive pre applied to the barrier.

A further alternative is to build the device directly onto a barrier material such as the aforementioned glass, plastic or metal based barrier materials, which could be either opaque or transparent depending on device architecture.

In a preferred embodiment of the invention, a series of channels are provided in the module, which upon tampering result in accelerated degradation of the solar module. The means by which they result in degradation are either by direct ingress of water vapour or oxygen leading to a device failure either directly through the degradation of the photoactive layers, or the initiation of a chemical process which results in either electrical shorting or becoming open circuit by virtue of interrupting the cell to cell or cell to busbar connection.

The channels may be formed by numerous means obvious to those skilled in the art. For instance they may be cut, imprinted, formed, etched, printed, embossed, produced by UV cross-linking a layer through a mask after which unexposed region is washed away, via direct laser cross-linking and wash-off or laser ablation of an applied layer amongst many others. The channels could be part buried in the PET substrate or formed into the barrier material. Optionally the channels could be prepared by structuring or patterning of the adhesive layer by any of the above mentioned methods, and applying the patterned adhesive to the module, for instance where use is made of a pressure sensitive adhesive.

The channels can also be formed by dewetting of deposited layers by printing a dewetting agent, such as for instance Fluoropel ^{TM} (Cytonix Corporation), in the desired channel pattern. A further method would be to deposit (e.g. print) a porous composition in the desired channel pattern which can the optionally be planarised with a further printing or coating step, or during the adhesive step. Even deposition of a material which produces a locally poor bond-line or itself have a high oxygen and/or moisture permeation rate would result in enhanced degradation upon exposure of the material ‘channel’ or pattern to air.

A further aspect of this invention is that the channels could be advantageously directed towards an area which contains an embedded IC or charge controlling circuitry, so that any attempt to remove or interfere with this unit would result in barrier rupture and exposure of the channels to air, thus activating or switching on the degradation mechanism leading to subsequent device failure.

A further option is for there to be liquids held in pockets or reservoirs to be released into the channels as a result of the rupture of the barrier via capillary action, potentially assisted by a pressure differential. An alternative approach here is for there to be a conductive fluid present in the channel and for this to leak away during barrier rupture, causing individual cell-stripe interconnections to become unconnected, thus stopping current flow through the module.

The aim of this invention is to provide a more secure solar cell which cannot easily be operated if stolen, or if used in a micropayment scheme, cannot easily be modified so that the micropayment scheme can be circumvented. The invention provides a means of (physically) disabling or reducing the power generating capability of a solar cell which optionally can contain an incorporated IC, prior to the connection terminals via disabling the capability of the device to provide power by interrupting the flow of current or build-up of voltage prior to the busbar of the photovoltaic device. The disabling effect is used to discourage theft or other tampering with the device.

The combination of both a physical security and an electronic security creates a more secure photovoltaic system with the advantage that the solar power generating component is difficult to separate and/or reuse. The current generating mechanism of the solar cell is impeded so that even if the cell was removed and rewired or re-attached to a different busbar it cannot readily generate current. In combination with the optionally in-built associated security electronics, or other security related electrical features, the intact solar panel will also refuse to work if the unit is stolen as the security mechanism requires a unique authorisation code or other key electronic signal before it is activated.

### BRIEF DESCRIPTION OF THE DRAWINGS

In order that the invention may be more fully understood, preferred embodiments of photovoltaic modules in accordance with the invention will now be described, by way of example only, and with reference to the accompanying drawings in which:

FIG. 1. Equivalent circuit of a solar cell

FIG. 2. Bypass diodes across each cell and multiple cells

FIG. 3. Multiple switch options for interrupting and hence disabling the power output of a module

FIG. 4 Multiple switches for short circuiting a cell and hence disabling the power output of the module

FIG. 5. Equivalent circuit and characteristics of a diode combined with a switch

FIG. 6. Passive switches in addition to the actively controlled switch to make the module tamper proof

FIG. 7. Passive switches in addition to the actively controlled switch to make the module tamper proof

FIG. 8. Light activated shorting of cells

FIG. 9. Back side light activated shorting of cells

FIG. 10. Solar cell interconnected in series where individual cells can be switched to short circuit by a signal provided via external, mounted on solar cell or embedded IC

FIG. 11 Switching by field effect transistors

FIG. 12 Switching transistor with bypass characteristic

FIG. 13. Resistive switching device

FIG. 14a. Example of an ideal location for IC or security device

FIG. 14b. Example of channel locations relative to an embedded IC

FIG. 15. Example of module with cell shadowing

FIG. 16. Example of typical thin film module with an embodiment of the present invention

FIG. 17a. A cross-sectional view of an embodiment of the invention illustrating a device with channels;

FIG. 17b. A cross-sectional view of an alternative embodiment of the invention illustrating a device with channels.

It is the purpose of this invention to make bypassing of solar module security features exceedingly challenging. Any tampering with a protected solar module will render it virtually unusable, by stopping or substantially limiting current or voltage from reaching at least one of the module bus bars. This is achieved in a number of ways which are best described by study of the solar cell and module equivalent circuits. An equivalent circuit is the simplest form of a more complex circuit in order to aid analysis.

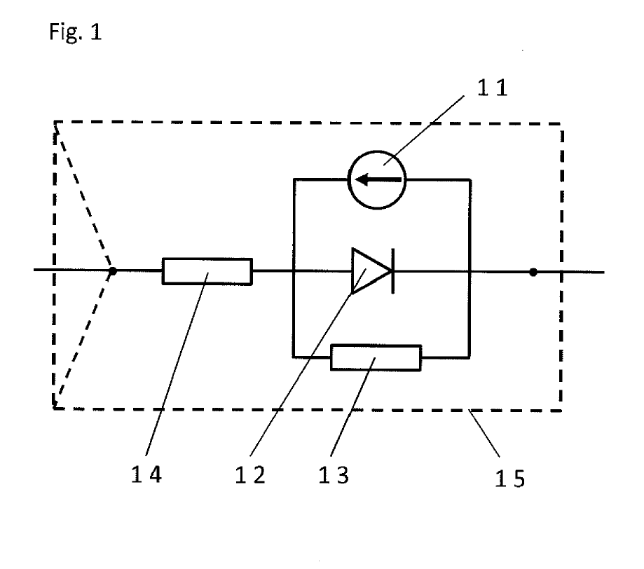

The electronic properties of solar cells and modules can be described by equivalent circuits consisting of discrete electronic components. The simple circuit of a solar cell (15) shown in FIG. 1, consists of a current generator (11). A diode (12) in parallel to the current generator represents the dark current characteristics. Additionally two resistors are connected, one in parallel (13) and one in series (14). Different types of solar cell can be described by variations of these equivalent circuits. It should be noted that equivalent circuits are a simplification of the actual circuit properties and are only used here to better elucidate parts of the invention.

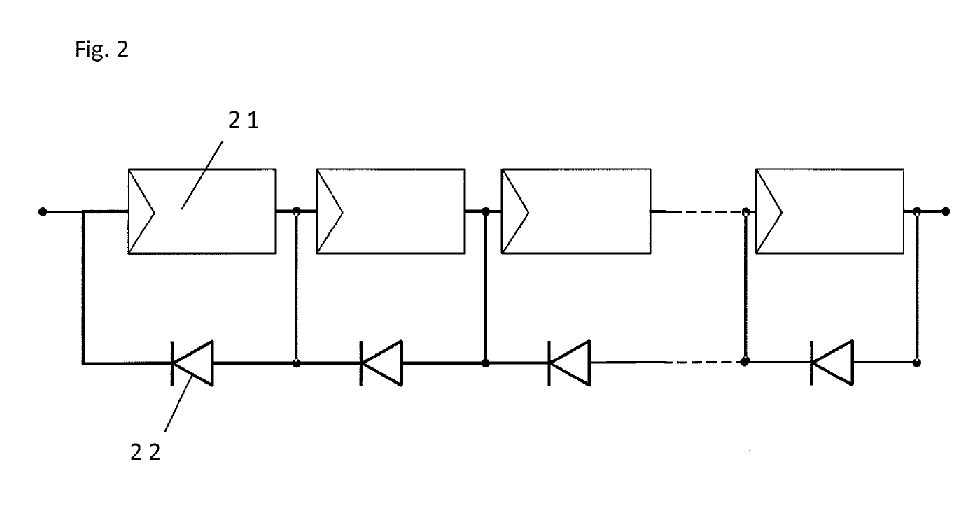

Solar modules consist of multiple solar cells interconnected in series or parallel. Also combinations of series and parallel interconnection are possible. The series interconnection of individual cells results in a build up of the voltage with a constant current flow through all interconnected cells (21 FIG. 2). Significant shadowing of individual cells results in a significant reduction of the generated current and the built up of a high resistivity. As a consequence the voltage build up by the adjacent cells will drop across the shadowed cell and can result in permanent damage. One mitigation approach is to connect bypass diodes to every individual cell or multiple of cells.

An individual photovoltaic cell typically produces a voltage in the range of 0.5 to 1.2 volts. Photovoltaic thin film modules are most often composed of consecutive cell stripes of thin film solar cells Adjacent cell are interconnected in series to generate useful summed voltages. These cell stripes are finally connected to current carrying busbars at each end of the module. These busbars are typically composed of relatively highly conductive material in order for there to be minimal resistance related losses as the current is passed through the busbar.

Busbars are typically either printed on to the solar module, using for instance a screen printer to deposit relatively thick (5-20 um) layer of silver paste, or a ribbon tape such as tinned copper or aluminium is affixed, which can be applied by known soldering methods or using conductive adhesive layers. The current is extracted from the solar module though the busbars via an optional peak power unit or other control mechanism, to the load on the solar cell. The load is typically one of a battery, an electricity grid (via an inverter) or some electrical device such as a pump, heater or other appliance. The electrode material, whilst having a conductivity and current carrying capability commensurate with carrying the current across the cell stripe to stripe, or stripe to busbar, typically across an area of no more than 1 cm, would not usually function at all well as a busbar due to the relatively thin layer deposited and would ordinarily be limited in its ability to deliver useful power due to a limited conductivity down an individual cell stripe which is typically in the range 20-200 cm long.

Many materials sets are utilised to prepare solar cells and each have their own advantages and disadvantages. Encapsulation requirement for the various technologies are quite different. Si based devices are typically encapsulated and protected from environmental factors with a barrier sheet which is often laminated on with EVA or optionally just coated in a weather proof resin. Other materials sets, such as those typically employed in for instance Organic Photovoltaics (OPV), dye sensitised (DSSC), CIGS and Cd/Te and hybrid organic/inorganic based solar cells, are typically very sensitive to water and oxygen ingress, and require a more sophisticated encapsulation, which contains a barrier layer designed to keep out oxygen and water vapour. Some forms of DSSC are particularly challenging due to their use of aggressive liquid electrolytes. Often glass is used for many alternative systems, as it is practically impervious to moisture and oxygen. Where cells are encapsulated with glass, it is naturally challenging to access the busbar—except where the busbar leaves the encapsulation. Alternative barrier materials are also available based on plastics. An opaque barrier can be as straight forward as aluminium evaporated onto plastic, which can be produced in long lengths at very low cost. Transparent barrier materials are somewhat more challenging, however, there are a number of sputtered oxide film stacks available, often composed of several inorganic/organic stacks to create tortuous pathways significantly reducing the propensity for the O2 and H2O molecules to penetrate to the active materials.

This invention provides a tamperproof switching mechanism for enabling and disabling the solar module in the event of theft, removal of the solar module or any attempt to bypass the electronic security mechanism. A preferred mechanism for electronically enabling and disabling the solar module is a signal either generated by an integrated circuit that is an integral component of the solar module (e.g. an integrated keypad) or is provided from an external source via an electrical connection. In the latter case the signal is
a) directly used for the enabling or disabling procedure. This can be a permanent, modulated (frequency) or temporal voltage or current OR
b) an encrypted signal that is provided to an integrated circuit on the solar cell.

An approved signal will result in a change of the switch status.

The disabling function (or function that significantly reduces the performance) can be achieved by : i) interruption of the current flow of the interconnected cells, ii) short circuiting of individual or multiple or all cells, iii) partial and complete shadowing of cells/module. Depending on the technical realisation the disabling function can be reversible or permanent.

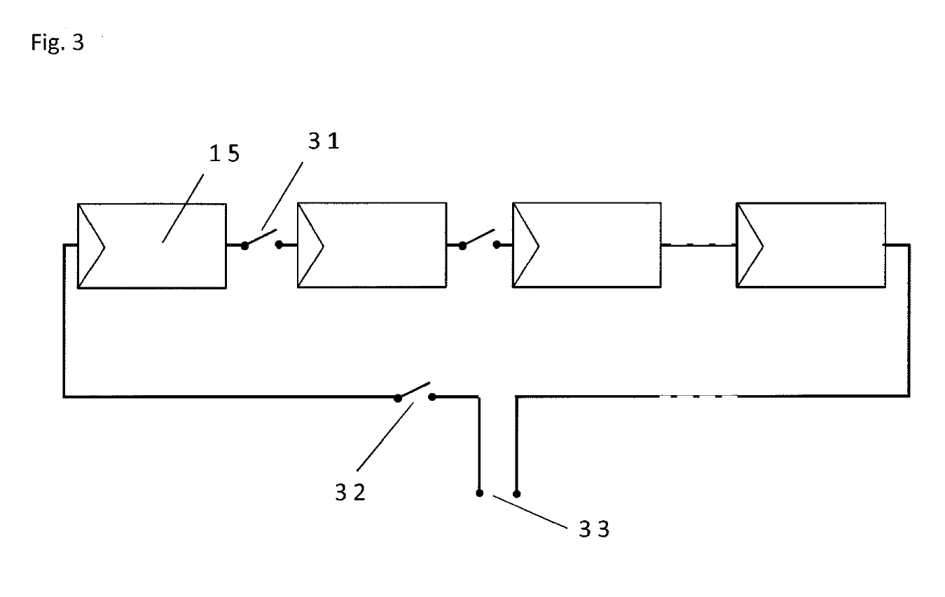

Interruption of the current flow can be done at various points of the solar module (FIG. 3). These are in between individual cells (31) or between the first and last cell and the respective end terminal (32).

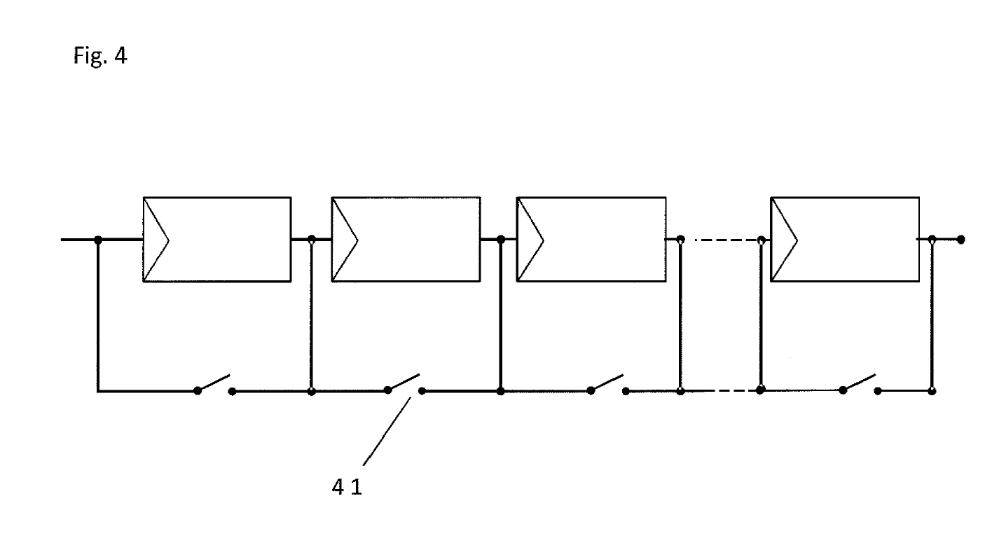

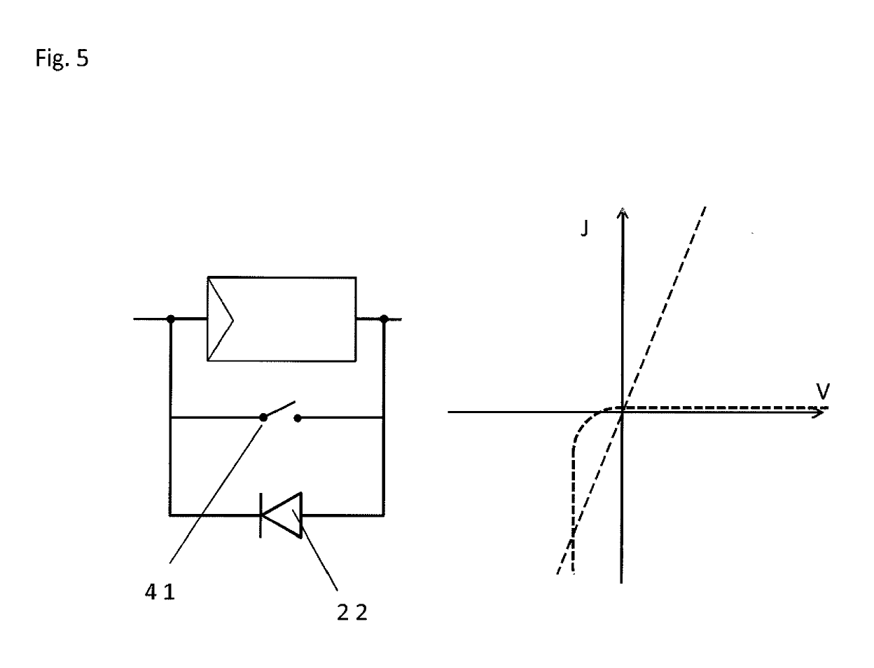

The short circuiting of cells can be done on the individual cell level, but also over multiple cells or the entire module. Short circuiting on the individual cell level would require to short circuit a number of cells to significantly reduce the performance of the module. FIG. 4 shows multiple switches (41) for short circuiting the cell and hence disabling the power output of the module. The switch for short circuiting of individual or multiple cells can be connected in parallel to bypass diodes. The electrical component can also combine the properties of a diode and a switch. FIG. 5 shows the circuit diagram of the preferred electrical characteristics of a diode (22) combined with a switch (41).

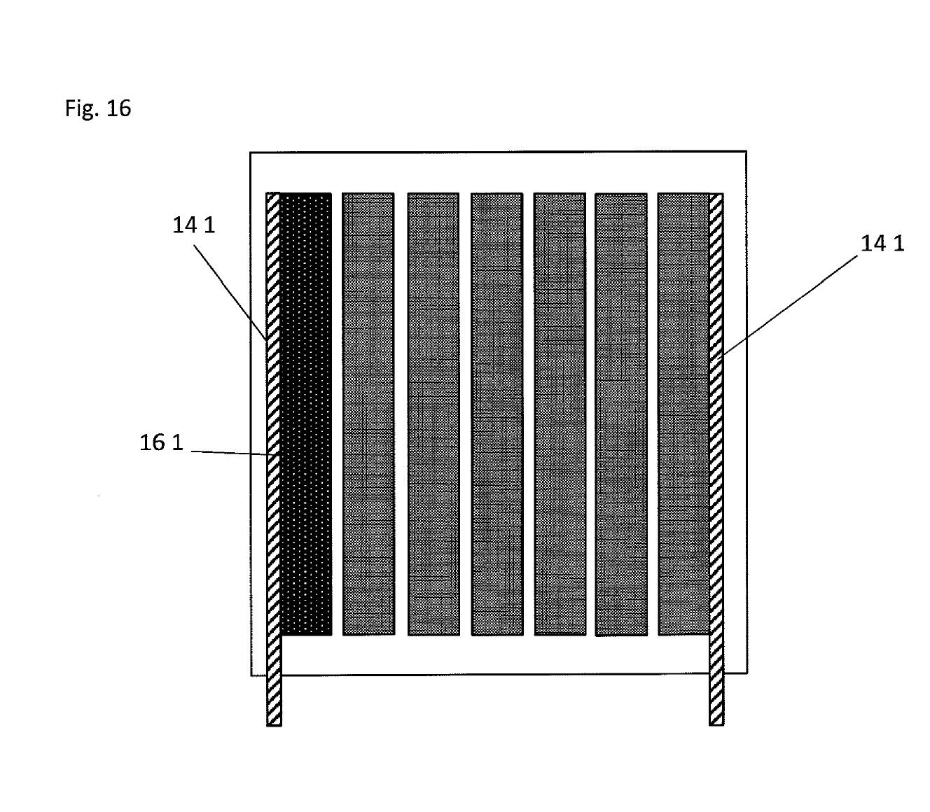

Partial or complete shadowing of a cell stripe can stop a solar module from working. FIG. 16 depicts a typical thin film solar module (161). If a whole cell area is shadowed (i.e. light is substantially prevented from falling on at least one of the cells, the module in the absence of bypass diodes.

Any tampering attempt to circumvent the above mechanisms would be by the physical or electronic manipulation of the status of the switch or by accessing the electrical contacts of the solar module. Therefore making the device tamper proof can be achieved by; destruction of integral components of the solar cell (semiconductor, injection layers) or by alteration of the current flow (short circuiting, interruption) whenever an attempt is made to manipulate the switch or obtain access to an electrical contact.

The following examples now illustrate these various ways in which the invention can be implemented.

### EXAMPLE 1

Reversible interruption between one terminal and the first solar cell in combination with a tamper proof access to the solar cell.

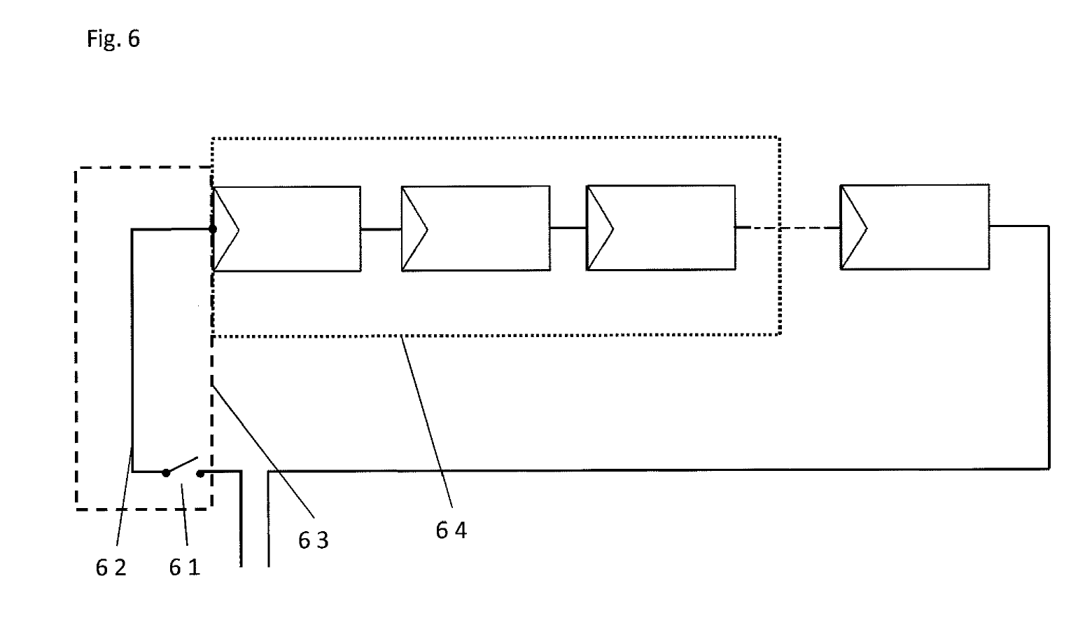

Reversible interruption between one terminal and the first solar cell can be realized by an integrated electronic switch (e.g. a transistor or relay) as a component of the integrated circuit. FIG. 6 represents the equivalent circuit. In order to achieve a tamper proof system, access to the switch (6 1) and to the current carrying lead (6 2) from the switch to the first cell and also any following cell must be prevented. Preventing access to the terminal of the first cell is most attractive as it represents the best target for accessing the module (Zone A (6 3)). This is due to it being a reliable contact to the module (thicker metal bus bar) and would allow a capture of the full module capacity. Electrical access to adjacent cells (Zone B (6 4)) is less attractive as the performance (voltage) will be lower, a reliable electrical contact is hard to realize and the lifetime of the solar module is likely to be affected by breaking the encapsulation, especially where they are susceptible to water or oxygen ingress.

To achieve insulation of the busbar to the cell stripe conductor upon unwanted tampering with the solar module, a switching mechanism based for instance on a chemical change or switch is initiated which removes or degrades the electrical interface between the stripe electrode and the busbar. This chemical switch can for instance be instigated as a result of oxidation or water (vapour) ingress as the material barrier is punctured. In this configuration, the conductive materials used to interface the busbar to the device would advantageously react to form substantially non-conductive oxides or hydroxides, and a metallic getter material such as barium, aluminium, magnesium, calcium, sodium, strontium or caesium can be employed. Alternatively a material which swells dramatically in the presence of moisture (for example dry starches, gels, other swellable polymers, certain mineral clays, or combinations thereof) can be used to electrically separate the electrode and busbar by swell-induced physical separation.

### EXAMPLE 2

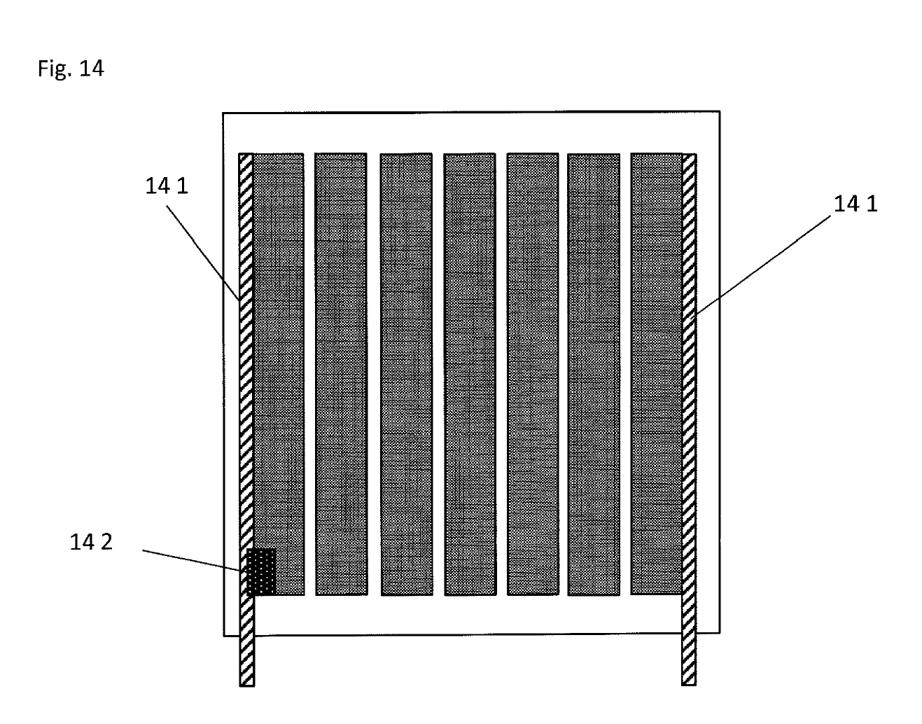

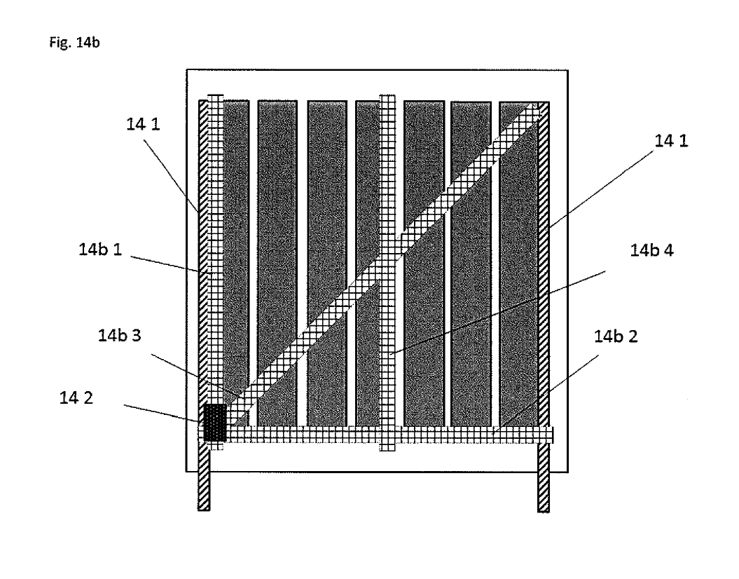

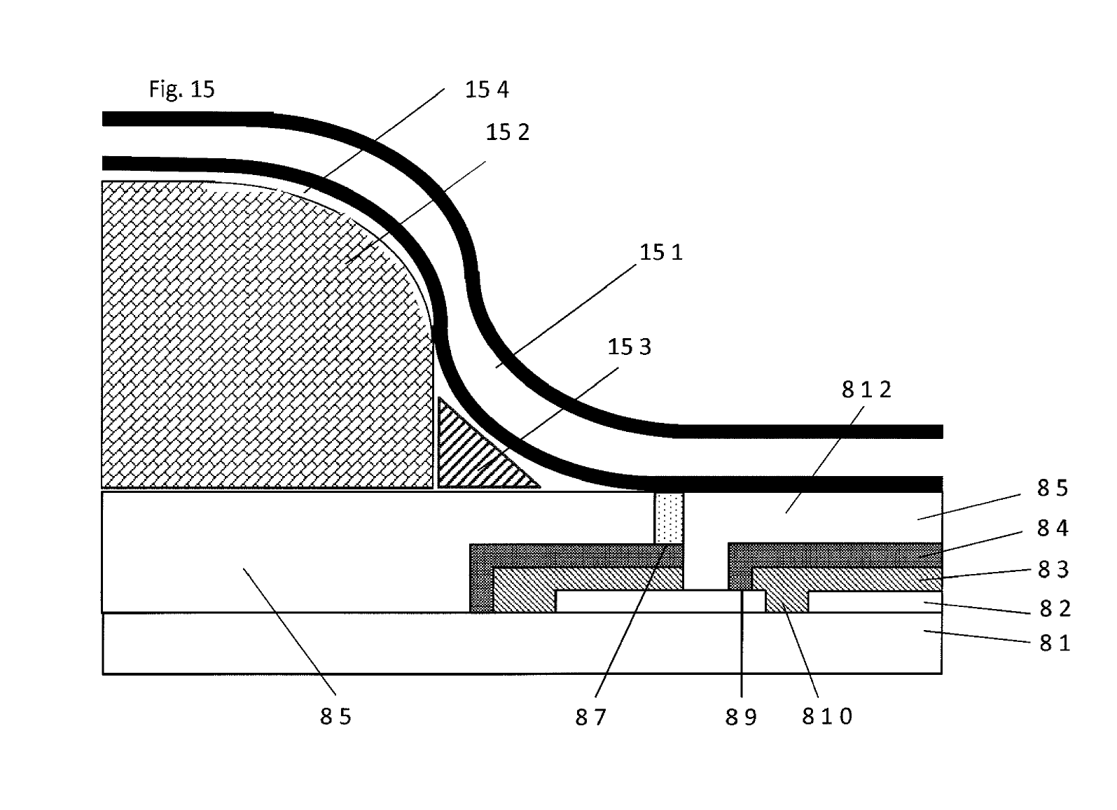

The IC is positioned in the solar module in such a way as to result in (pre-formed) channels being revealed which result in device failure upon removal of, or damage to the area around, the IC. An example of a useful location of the IC or security feature is depicted in FIG. 14a. The busbars (14 1) are in this case at the edge of the module, and the IC or security device (14 2) is embedded under the encapsulation over the connection between one of the busbars and the left hand cell electrode (8 5). The channels can be air pockets, or filled with materials which react with components in the air (for instance oxygen and moisture). FIG. 15 illustrate a channel formed at the junction of the thick busbar (15 2) and the top electrode once a encapsulation sheet (151) is applied. The encapsulation is ordinarily applied with via an adhesive (15 4) which can be selected from a pressure sensitive adhesive, a thermal cure adhesive, an epoxy or a UV cure adhesive, without wishing to be limited, depending on the solar cell materials chosen. The first of these options is especially preferred for those solar cell materials systems in which oxygen or moisture exposure of the active areas result in significant performance degradation. In some instances even just the fracturing of the barrier properties of the encapsulation would lead to a gradual, but eventually catastrophic, degradation of device performance via oxygen and moisture vapour ingress, and in this case the barrier material being perforated acts as the physical switch. However a series of strategically placed channels under the IC (or near the IC electrical contacts) would greatly accelerate the failure of the device if the IC is removed, or the contacts are tampered with through the barrier material. A channel can optionally be generated by a barrier material laminated to a busbar connector tape or wire which sits proud of the substrate, leaving a gap where the lamination adhesive does not immediately contact the electrode.

Where the solar cell material system is not itself particularly air or moisture sensitive, these channels can be filled with a material which reacts with oxygen or moisture to generate an aggressive chemical which attacks the electrode material, an example being white phosphorous which releases a strong acid. Alternatively the interface between the electrode and the busbar, or the electrode itself in that area can be made of a material which does react strongly with oxygen or moisture. This interface or electrode material can for instance be selected from the known rapidly oxide forming metals materials such as aluminium, calcium, sodium.

An advantageous approach for systems which are sensitive to oxygen or water vapour to some degree is to include a level of getter material in the channels. This would provide a lifetime improvement for the devices, but when the O2/H2O barrier is perforated, still lead to cells failing as the getter material is consumed. Known getter materials are e.g. evaporated (flashed getters) barium, aluminium, magnesium, calcium, sodium, strontium, caesium or phosphorous or humidity getters such as Dynic HG sheet, Sud-Chemie Desi Paste, Zeolites and Zeolitic clays are well known in the art.

FIG. 14b illustrates where some of the options are for channel locations. In this instance the module has an embedded circuit (14 2) and the channel structures (14b 1-4) are partly either over or under the embedded circuit to ensure maximum degradation upon tampering with the embedded circuit. As depicted the features can run parallel, perpendicular, at an angle, or a combination thereof, to the cell stripe direction. The preferred channel position will be largely dependent on the method chosen to interrupt the current flow, as certain configurations will result in faster degradation than others.

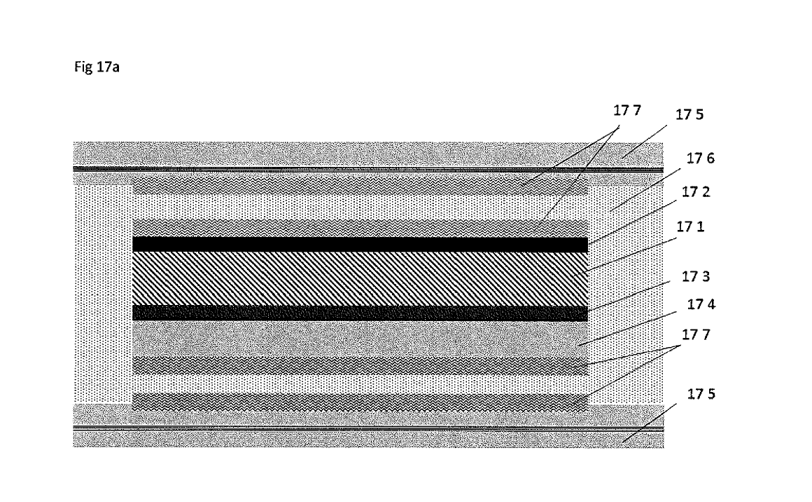

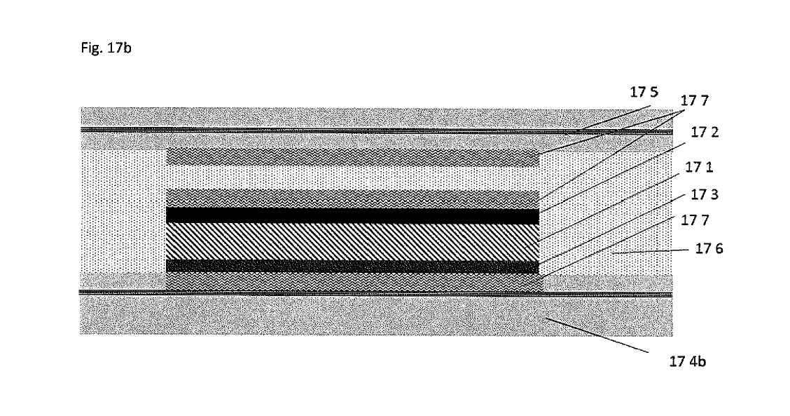

The location of the channels relative to the layers of a typical 3rd generation solar cell is depicted in drawing 17a and 17b. In 17a a cross-section of an encapsulation structure of a cell produced on a standard PET substrate is illustrated along the cell stripe direction. The photoactive layer(s) (including injection layers), 17 1, is prepared between two electrode 17 2 and 17 3. The bottom electrode 17 3 is attached to the PET substrate, 17 4. This whole structure is encapsulated between two barrier sheets, 17 5, using some form of adhesive, 17 6. Some of the regions where channels could usefully be formed are depicted, 17 7. FIG. 17b depicts a schematic of an encapsulated solar module stripe which produced directly onto a barrier material. Here, the photoactive materials 17 1, and electrodes 17 2 and 17 3 are deposited directly onto a barrier material 17 4b. The final top barrier material, 17 5, is attached to the device using an adhesive, 17 6.

### EXAMPLE 3

This approach is to make use of a channel which is filled with a conductive liquid for making a vital connection, which would leak away when the rupturing takes place. Without wishing to be limiting, such liquid can be one of the following; an ionic liquid e.g. 1-ethyl-3-methylimidazolium dicyanamide, (C₂H₅)(CH₃)C₃H₃N⁺₂.N(CN)⁻₂ and 1-butyl-3,5-dimethylpyridinium bromide, a solution of electrolyte -for some solar cell materials this would preferably not be aqueous, but an inorganic liquid/solvent. Exemplary organic solvents include but are not limited to nitriles such as acetonitrile, acrylonitrile and propionitrile; sulfoxides such as dimethyl, diethyl, ethyl methyl and benzylmethyl sulfoxide; amides such as dimethyl formamide and pyrrolidones such as N-methylpyrrolidone and carbonates such as propylene carbonate. Exemplory electrolyte salts include quaternary ammonium salts such as tetraethylammonium tetrafluoroborate ((Et)₄ NBF₄), hexasubstituted guanidinium salts such as disclosed in U.S. Pat. No. 5,726,856). Finally a liquid metals or alloys such as mercury, gallium, sodium-potassium or galinstan can be used. Capillary force can be designed in as the way to induce liquid flow upon rupturing.

Capillary force is also desirable as a means to transport aggressive chemicals or etchants such as for example acids to the key interfaces. In this case a dam would need to be broken by the physical act of rupturing the encapsulation or removing the IC, allowing the liquid stored in a reservoir to be released. Preferably the liquid is contained under the encapsulation.

In terms of ensuring that the IC removal creates the structure required, it is desirable to use a stripping layer and a strong adhesive such as cyanoacrylates, so that IC removal is guaranteed to reveal the channels via delamination.

### EXAMPLE 4

Irreversible short circuiting of individual or multiple cells caused by attempts of tampering is achieved via light activation. The mechanism for disabling the module is by light activated short circuiting (light sensitive switch (7 1)) of multiple cells during the attempt of getting access to the switch (3 2) or to the electrical connection between switch and first solar cell. The light sensitive switches are covered by an opaque protective layer (7 2) that serves as a cover for electrical leads and the switch box.

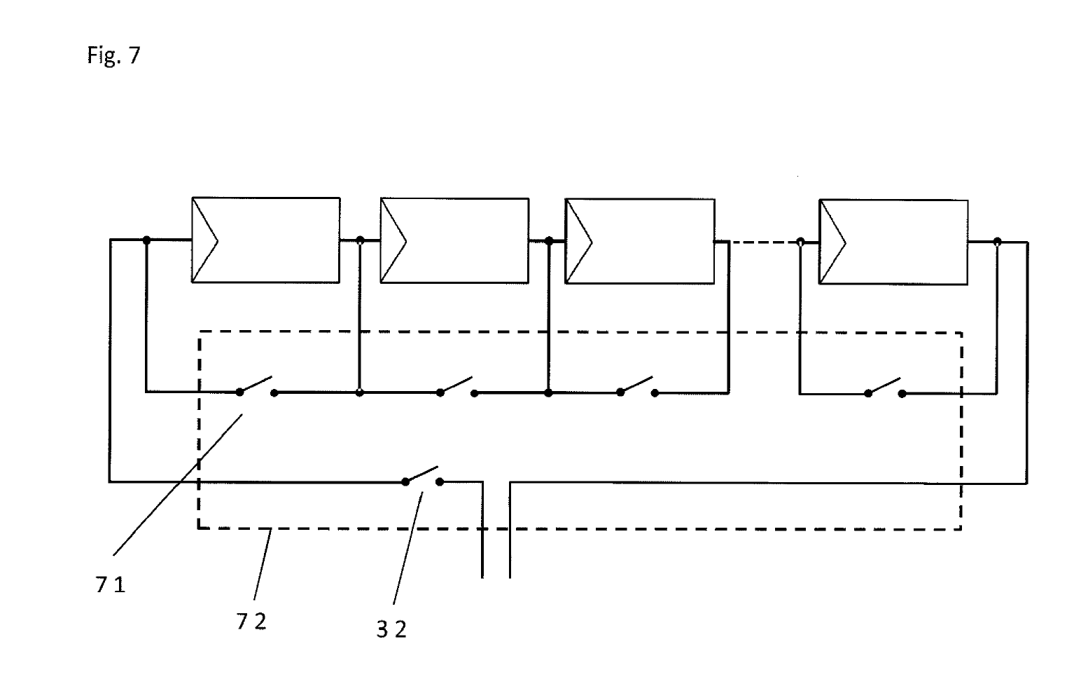

Removal of the cover leads to a light exposure of the switches and hence to a shortening of the cells. The equivalent circuit is shown in FIG. 7.

The light sensitive component switches from an ohmic behaviour of low resistivity (short circuit) to a diode characteristics under illumination. The resistivity is low enough to result in a significant voltage drop of the solar cell. In its diode mode, the electrical characteristics of the component (e.g. turn on voltage) is appropriate to protect the cell(s) from built up of high voltages upon shadowing of fractions of the module (FIG. 5).

A preferred method of generating a photo activated switch is via a mechanism based on ZnO. The absorption of oxygen to ZnO is known to significantly reduce its conductivity by removing charge carriers from the conduction band. Exposure by solar irradiation (with sufficient UV) causes the desorption of oxygen and hence increases the conductivity. A ZnO based diode could function as a photosensitive diode switch. This behaviour is known and was shown in several publications, for example Jin et al, Solution-Processed Ultraviolet Photodetectors Based on Colloidal ZnO Nanoparticles, NANO LETTERS 2008, Vol. 8, No. 6, 1649-1653, Olson, D. et al, The Effect of Atmosphere and ZnO Morphology on the Performance of Hybrid Poly(3-hexylthiophene)/ZnO Nanofiber Photovoltaic Devices, J. Phys. Chem. C 2007, 111, 16670-16678 and Mandalapu et al. Mater. Res. Soc. Symp. Proc. Vol. 891, 2006 Materials Research Society, 0891-EE08-07.1.

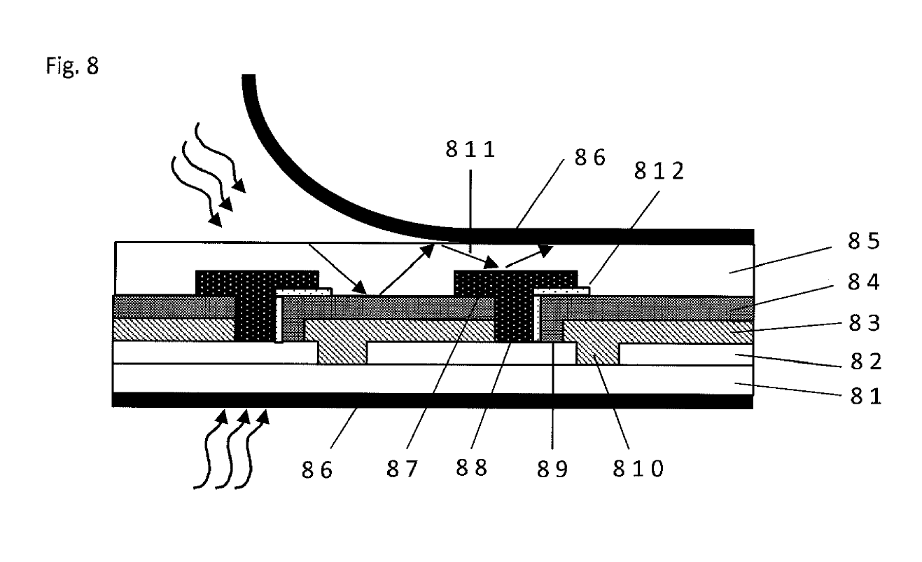

The implementation of photosensitive switches in a thin film solar module is shown in FIG. 8. The cross section shows the substrate (8 1), followed by patterned electrode (8 2), photoactive layer (8 3) and patterned top electrode (8 4) an encapsulation layer and two opaque covers (8 6). The gap between the top electrodes is partially (not over the entire length of the module) covered with the light sensitive conductor (8.8) (e.g. ZnO).

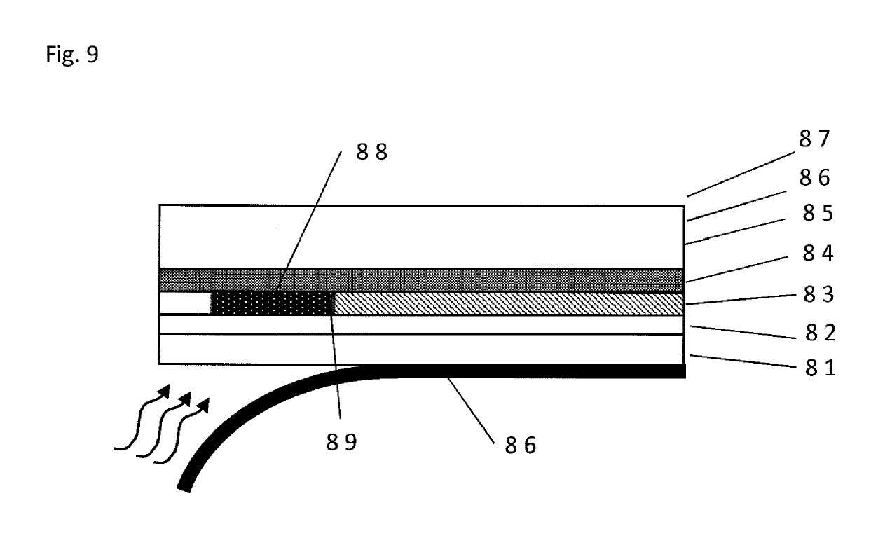

One side of the gap (depending on the polarity of the solar cell) can be covered with a p-semi-conductor (8 1 2) in order to form the required bypass diode. Turned to its conductive state, the short circuit current will flow directly from top electrode to the bottom electrode (shortest distance (thickness of the photoactive layer)). The illumination is effective from both sides of the module as soon as the cover is removed. The effect can be enhanced by introducing light guiding features (8 1 1) (metalized cover). Even the partial removal of the masking tape will result in an increase of the conductivity. Alternatively, the photosensitive layer can be incorporated between the two electrodes, next to the semiconductor (FIG. 9). This configuration allows for larger currents through the increased interface area.

### EXAMPLE 5

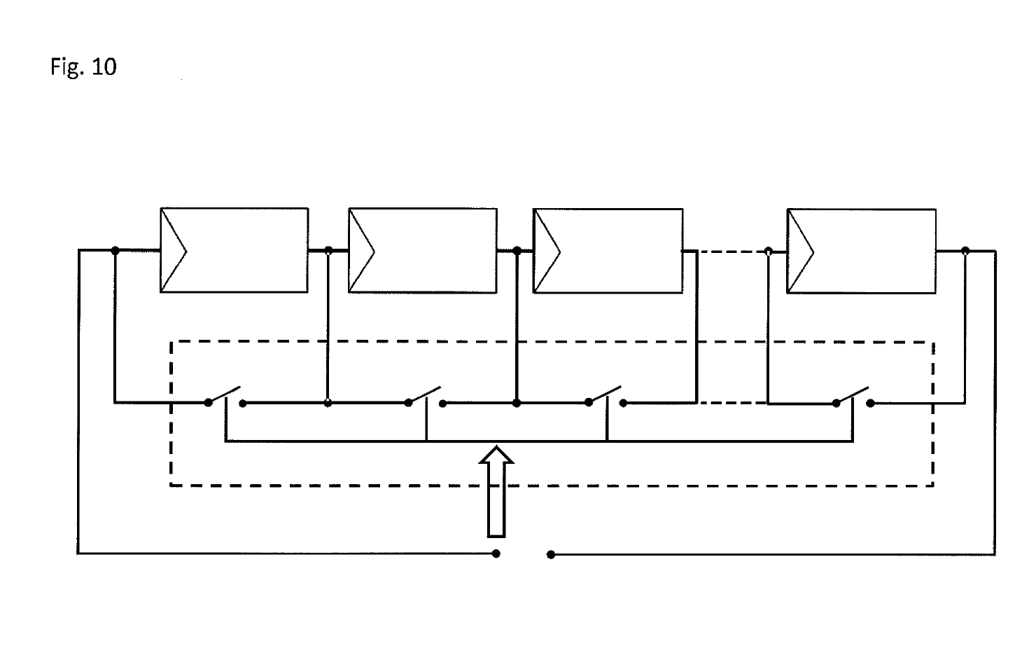

A highly integrated reversible tamper proof switching mechanism is provided by one or multiple components (switches) that can reversibly turned from ohmic (short circuit between solar cell electrodes) to highly resistive (insulating) or diodic characteristic (see FIG. 10). The signal for switching is provided by either the integrated circuit or from an external source. The high degree of integration as described below will make the system tamper proof.

### Types of Switches and Realization in Thin Film Modules

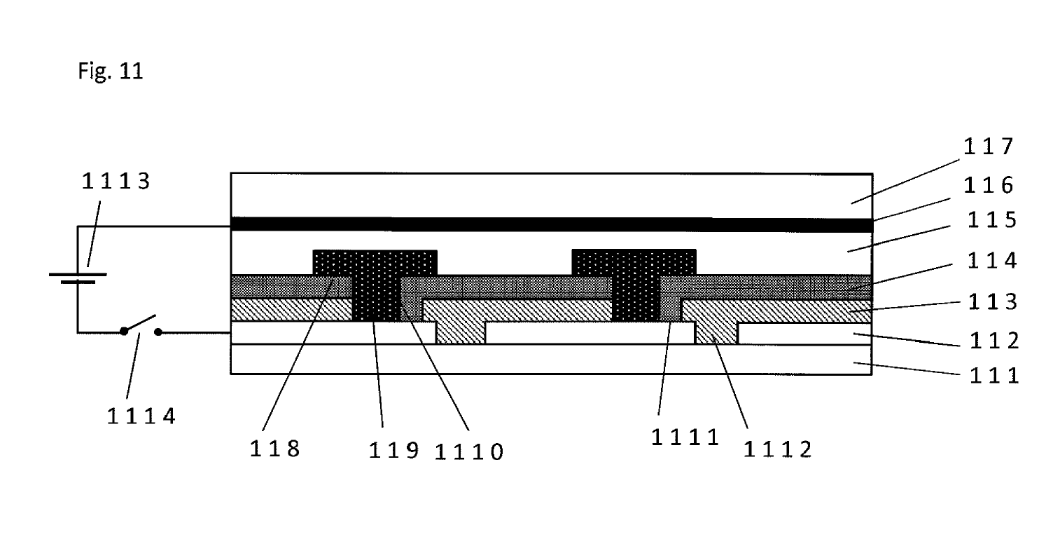

FIG. 11 shows a configuration with switches integrated into a thin film module.

### EXAMPLE 5a)

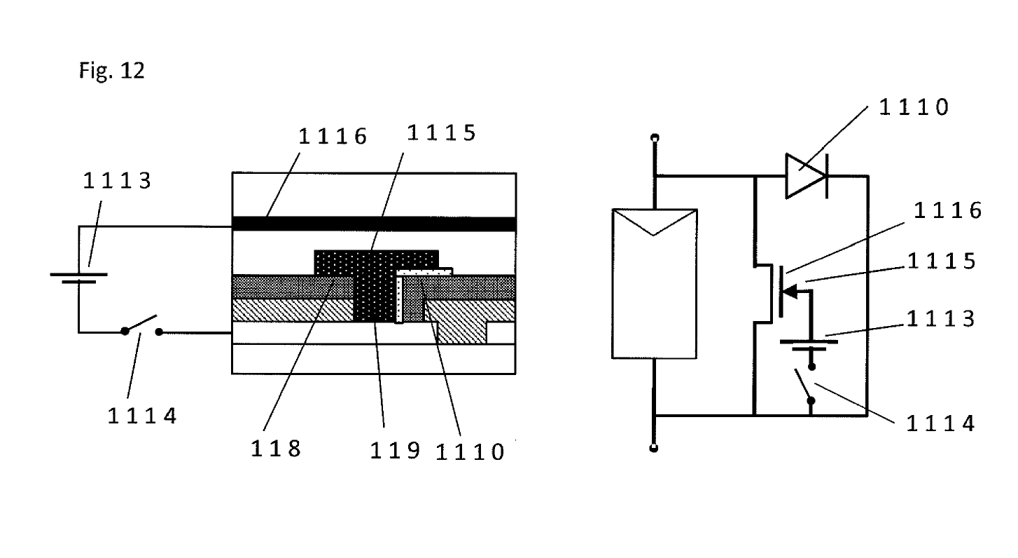

Switching by field effect transistors: The leakage current that will disable the solar cells is represented by the current from source to drain. Source and drain are represented by the top and bottom electrode (connected to the adjacent top electrode). The gate electrode (116) is separated by a dielectric layer (115) (for example an encapsulation adhesive) from the electrodes. An external voltage will be supplied for switching (1 1 1 4) of the transistor (1 1 1 3). This voltage can be partially built up by the module itself and partially provided by the security module. The energy consumption is low, as there is no current flowing. FIG. 12 shows the transistor configuration with the bypass characteristic included and the corresponding equivalent circuit. The transistor is present in the so called vertical channel configuration. The effective channel is determined by the thickness of the photoactive layer. The bypass diode is represented by (1 1 1 0)

### EXAMPLE 5b)

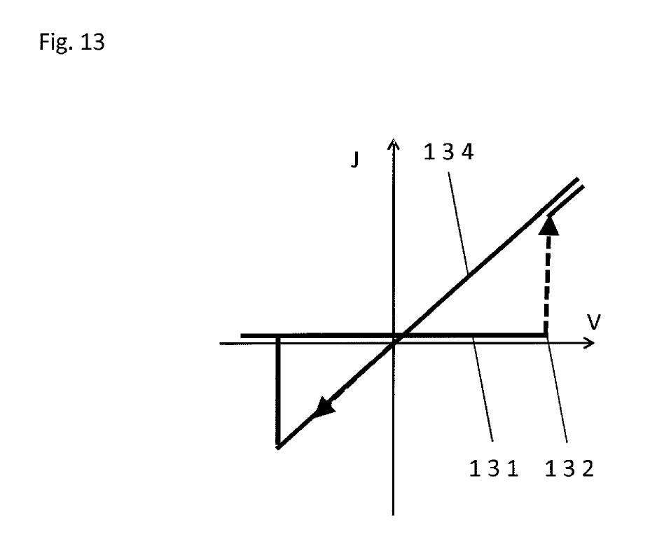

Resistive-switching devices as described in the review article by Quoyang et al (Ouyang, J. Nano Reviews 2010, 1: 5118), are two terminal devices using nanomaterials as the active components, including metal and semiconductor nanoparticles. The status can be changed from highly restive to conductive by applying a threshold voltage (see FIG. 13). This voltage pulse can be applied by the tamper proof control box. Disabling of the module requires a reverse bias voltage pulse above a certain threshold (132) (opposite to the operation voltage of the module). Enabling of the module requires a voltage pulse of the opposite polarity.

### EXAMPLE 5c)

Switchable diodes are two-terminal devices that allow reversible switching from diode characteristics to highlyconductive. The switching is carried out by applying a bias voltage. The mechanism is based on the modulation of shottky barriers by polarization.

A switchable ferroelectric diode effect and its physical mechanism in Pt/BiFeO3/SrRuO3 thin-film capacitors was reported by Lee et al (Phys. Rev. B 84, 125305 Polarity control of carrier injection at ferroelectric/metal interfaces for electrically switchable diode and photovoltaic effects, 2011).

### EXAMPLE 5d)

Micromechanical switches switched by electrostatic actuation can alternatively be implemented.

### EXAMPLE 6

Cell stripe(s) can be affected in the cell series connections along the module by capillary wicking of liquid induced by tampering (e.g. attempted removal of IC or other security features). This requires channels to be cut or formed into the substrate and a reservoir with an appropriate ‘dam’ which is broken during barrier destruction. An option is to use channels that may exist as a result of the busbar connection and separation at the edge to a laminated encapsulation material as shown in example 2. Options include using a conductive liquid to shorts cells. Such liquid can be one of the following; an ionic liquid e.g. 1-ethyl-3-methylimidazolium dicyanamide, (C₂H₅)(CH₃)C₃H₃N⁺₂.N(CN)⁻₂ and 1-butyl-3,5-dimethylpyridinium bromide, a solution of electrolyte -for some solar cell materials this would preferably not be aqueous, but an inorganic liquid/solvent. Exemplary organic solvents include but are not limited to nitriles such as acetonitrile, acrylonitrile and propionitrile; sulfoxides such as dimethyl, diethyl, ethyl methyl and benzylmethyl sulfoxide; amides such as dimethyl formamide and pyrrolidones such as N-methylpyrrolidone and carbonates such as propylene carbonate. Exemplory electrolyte salts include quaternary ammonium salts such as tetraethylammonium tetrafluoroborate ((Et)₄ NBF₄), hexasubstituted guanidinium salts such as disclosed in U.S. Pat. No. 5,726,856). Finally a liquid metals or alloys such as mercury, gallium, sodium-potassium or galinstan.

### EXMAPLE 7

A substantially transparent layer of material which turns opaque upon tampering is added either over the solar module or over one or more individual stripes.

This example is achieved via a dye or combination of dyes being generated and covering the active area stopping the cell from working correctly, whilst at the same time being tamper evident. This is illustrated in FIG. 16 one of the cell stripes is shown to be darkened (16 1). It should be noted that any cell could in principle be chosen. One advantage is that the dye(s) would not necessarily have to be inside final encapsulation. Dyes include, but are not restricted to, one or more Leuco dyes, such as crystal violet lactone (pH switching, coloured at low pH), phenolphthalein, thymolphthalein (pH switching, coloured at high Ph). Alternatively colour couplers could be used, as could any known materials which react with oxygen or moisture to produce strong colours. A further alternative is to use elercrochromic dyes or bistable liquid crystals, which have a transparent state and an opaque state. The transparent state could be maintained by regular pulses at minute, day, month intervals depending on the requirements of the bistable liquid crystal. An example of a bistable liquid crystal is for instance produced by E-Ink.

### EXAMPLE 8

Capillary wicking of liquid dye can be induced. This requires channels to be cut or formed into substrate and a reservoir of the liquid provided with an appropriate ‘dam’ which is broken during barrier destruction. Any know dyes or combination of dyes can be used, so long as they have sufficient optical absorption and are soluble in the solvent used.

The examples are illustrative of the invention and anyone skilled in the art will realise a combination or variations of any of the above approaches could be utilised to provide a tamperproof solar module system.

1. A photovoltaic device comprising:
at least one photovoltaic cell housed within an encapsulant forming a protective barrier for the at least one photovoltaic cell;
a switch operable to allow delivery of electricity from the device; and
means, also housed within the encapsulant, to render the device inoperable, preferably permanently inoperable, upon tampering with the device.

2. A photovoltaic device as claimed in claim 1, wherein the encapsulant comprises a barrier layer over front and back sides of the device.

3. A photovoltaic device as claimed in claim 1 or 2, wherein the means to render the device inoperable are located adjacent an electrode, either an anode or cathode electrode.

4. A photovoltaic device as claimed in claim 1 or 2, wherein the means to render the device inoperable are located between a substrate supporting an electrode and the encapsulant.

5. A photovoltaic device as claim in any preceding claim, wherein the switch is also housed within the encapsulant.

6. A photovoltaic device according to any preceding claim, wherein the switch is controlled by an integrated circuit.

7. A photovoltaic device according to any preceding claim, wherein integrated circuit and/or switch comprises an integral component of the PV device.

8. A photovoltaic device according to any preceding Claim comprising a terminal for connection to a load.

9. A photovoltaic device according to claim 8, wherein the means to render the device inoperable is positioned upstream or downstream of the terminal.

10. A photovoltaic device according to any preceding Claim comprising a plurality, i.e. two, three or more, photovoltaic cells.

11. A photovoltaic device according to claim 10, wherein the means to render the device inoperable is located between individual cells and/or between the first and/or last cell and a respective terminal.

12. A photovoltaic device according to claim 10, wherein the means to render the device inoperable is located before or adjacent to the busbar which forms a connection between the module and the terminal to the load.

13. A photovoltaic device according to any of claims 10 to 12, wherein the means to render the device inoperable comprises means to short circuit at least one cell of a photovoltaic module.

14. A photovoltaic device according to any of claims 10 to 13, wherein the means to render the device inoperable comprises means to short circuit every cell.

15. A photovoltaic device according to any of claims 10 to 12, wherein the means to render the device inoperable may comprise means to at least partially inhibit, e.g. to interrupt, the current flow of interconnected cells.

16. A photovoltaic device according to any of claims 10 to 15, wherein the means to short circuit the at least one cell may be connected in parallel to a bypass diode.

17. A photovoltaic device according to any preceding Claim, wherein the means to render the device inoperable may comprise means to partially or completely interfere with collection of solar energy (e.g. to shade) the at least one cell.

18. A photovoltaic device according to any preceding Claim, wherein the means to render the device inoperable comprises channels which are revealed upon tampering with the switch and/or, if present, the integrated circuit.

19. A photovoltaic device according to claim 18, wherein the channels are formed within the encapsulant at a side facing the at least one photovoltaic cell.

20. A photovoltaic device according to claim 18 or 19, wherein the channels are formed within a substrate supporting an electrode upon which at least one layer of the at least one photovoltaic cell is mounted.

21. A photovoltaic device according to claim 18, wherein the channels comprise air pockets or are filled with materials which react with components in the air, e.g. oxygen and/or moisture.

22. A photovoltaic device according to claim 21 where the device further comprises a getter material, e.g. evaporated (flashed getters), barium, aluminium, magnesium, calcium, sodium, strontium, caesium, phosphorous, humidity getters such as Dynic HG sheet, Sud-Chemie Desi Paste, Zeolites or Zeolitic clays.

23. A photovoltaic device according to any preceding Claim, wherein the means to render the device inoperable may comprise a chemical switch.

24. A photovoltaic device according to claim 23, wherein the chemical switch is adapted to remove or degrade the electrical interface between a stripe electrode and the or a busbar.

25. A photovoltaic device according to claim 23 or claim 24, wherein the chemical switch may be instigated as a result of oxidation or water (vapour) ingress after puncture of a barrier.

26. A photovoltaic device according to any of claims 23 to 25, wherein the chemical switch may comprise a material which reacts with oxygen or moisture to generate an aggressive chemical which attacks a component of the device e.g. an electrode material, e.g. the material may comprise white phosphorous.

27. A photovoltaic device according to any of claims 23 to 26, wherein the means to render the device inoperable may comprise a material which swells in the presence of moisture, e.g. a dry starch, gel, swellable polymer, a mineral clay, or a combination thereof, to electrically separate the electrode and the busbar by swell induced physical separation.

28. A photovoltaic device according to any preceding Claim, wherein the means to render the device inoperable may comprise a conductive liquid which makes a vital connection (for example between the or a busbar and the or a stripe electrode) which leaks away upon tampering with the switch.

29. A photovoltaic device according to any of claims 1 to 27, wherein the means to render the device inoperable may comprise a conductive liquid which short circuits the at least one cell on tampering with the switch.

30. A photovoltaic device according to claim 28 or claim 29, wherein the conductive liquid may comprise an ionic liquid e.g. 1-ethyl-3-methylimidazolium dicyanamide, (C₂H₅)(CH₃)C₃H₃N⁺₂.N(CN)⁻₂ or 1-butyl-3,5-dimethylpyridinium bromide; a solution of electrolyte e.g. an inorganic liquid/solvent, for example the solvent may comprise, a nitrile such as acetonitrile, acrylonitrile or propionitrile, a sulfoxide such as dimethyl, diethyl, ethyl methyl and benzylmethyl sulfoxide, an amide such as dimethyl formamide and pyrrolidones such as N-methylpyrrolidone or a carbonate such as propylene carbonate and the electrolyte salt may comprise quaternary ammonium salts such as tetraethylammonium tetrafluoroborate ((Et)₄ NBF₄), hexasubstituted guanidinium salts; or a liquid metal or alloy such as mercury, gallium, sodium-potassium or galinstan.

31. A photovoltaic device according to any of claims 28 to 30, wherein capillary force is used to induce the liquid to flow, upon tampering.

32. A photovoltaic device according to any preceding Claim, wherein the means to render the device inoperable comprises a corrosive or aggressive liquid chemical, chemicals or etchants delivered to key interfaces, e.g. by capillary force.

33. A photovoltaic device according to any of claims 28 to 32, wherein the liquid is stored in a reservoir and is released upon tampering.

34. A device according to any claims 13 and 14, wherein the means to render the device inoperable comprises light activated short circuiting.

35. A device according to claim 34, wherein the means to render the device inoperable further comprises light guiding features.

36. A device according to claim 34 or claim 35, wherein the means to render the cell inoperable comprises a ZnO photosensitive diode switch.

37. A device according to any of claims 13 and 14, wherein the means to render the device inoperable comprises at least one field effect transistor.

38. A device according to claim 37 where the transistor drain and source are connected to the opposite electrodes of at least on solar cell.

39. A device according to claims 37 and 38 where the gate for one, and the common gate for multiple transitors, is controlled by a tamper proof control box.

40. A device according to the claim 17, wherein the means to render the device inoperable comprises at least one switchable diode with its terminals connected to the opposite electrodes of at least one solar cell, capable of switching from diode characteristics to highly conductive.

41. A device according to the claims 17 and 18, wherein the means to render the device inoperable comprises at least one switchable diode (switching from diode characteristics to highly conductive) with its terminals connected to the opposite electrodes of at least on solar cell, capable of switching from diode characteristics to highly conductive.

42. A device according to claims 17 and 18, wherein the means to render the device inoperable comprises at least one resistive switching device with its terminals connected to the opposite electrodes of at least one solar cell.

43. A device according to claims 37 to 42, wherein switching device (transistor, switchable diode, resistive switching device) is controlled by an electrical signal provided by a tamper proof control box.

44. A device according to the claims 34 to 42, wherein the means to render the device inoperable is based on organic, inorganic or metal thin films.

45. A device according to the claims 34 and 42, wherein the means to render the device inoperable is incorporated by coating, printing or patterning techniques.

46. A device according to claim 17, wherein the means to render the device inoperable comprises a substantially transparent layer of material which turns opaque upon tampering with the switch.

47. A device according to claim 46, wherein the layer comprises a dye, such as a Leuco dyes, e.g. crystal violet lactone, phenolphthalein, or thymolphthalein.

48. A device according to claim 46, wherein the layer comprises an electrochromic dye or dyes or a bistable liquid crystal.

49. A device according to claim 46, wherein the means to render the device inoperable comprises a liquid dye.

50. A device according to claim 49, wherein the liquid is stored in a reservoir and is released upon tampering.

51. A device according to claim 49 or claim 50, wherein the liquid is stored under encapsulation.

52. A photovoltaic device according to any preceding Claim, wherein the photovoltaic cell is an organic photovoltaic cell.
